(19) United States
(12) Patent Application Publication
(10) Pub. No.: US 2009/0034181 A1
(43) Pub. Date: Feb. 5, 2009

(54) CORDLESS POWER SOLUTION FOR RACK-MOUNTED DEVICES

(75) Inventor: Zbigniew Gizycki, San Jose, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(73) Assignee: HEWLETT-PACKARD DEVELOPMENT COMPANY, L.P., Houston, TX (US)

(21) Appl. No.: 11/831,945

(22) Filed: Jul. 31, 2007

(51) Int. Cl. H05K 7/14; H01R 25/16

(52) U.S. Cl. 361/683; 361/727; 361/822

(57) ABSTRACT

A power rail comprises a portion for mounting an electrical device and at least a conductor having a surface which is at least partially un-insulated and exposed for contact with a power terminal of the electrical device, for cordlessly supplying power to the electrical device when the electrical device is mounted to the portion of the power rail.

### BACKGROUND

In a rack-mounted computer system, each computer is mounted in a rack and each rack may house one or more computers wherein each computer has at least one power cord. Multiple power cords, e.g., as many as 5, may be required for failover protection of a single computer if the computer is an important component of the system. Thus, a rack that houses several computers will have many power cords for supplying power to the system. This leads to a need for multiple power distribution units (PDUs) and/or power strips to accommodate various plugs of the power cords which causes further installation problems. As density of power, and hence the number and/or size of the power cords, within the rack is growing, there is insufficient space left for other cables, such as network cabling the demand for which is on the rise, on the back of the system. Additionally, EMI (electromagnetic interference) or RFI (radio frequency interference) issues occur when networking cables cross multiple high power, unshielded power cords.

### DESCRIPTION OF THE DRAWINGS

One or more embodiments are illustrated by way of example, and not by limitation, in the figures of the accompanying drawings, wherein elements having the same reference numeral designations represent like elements throughout and wherein:

FIG. 1 is a simplified, perspective view of a rack according to an embodiment;

FIG. 2 is a partial, perspective view showing the attachment of horizontal rails and vertical bars in a rack;

FIG. 3 is a partially cutaway, perspective view of a power rail according to another embodiment;

FIG. 4 is a simplified, cross-sectional view showing a power rail in use with an electrical device according to another embodiment;

FIG. 5 is a simplified, perspective view of an electrical device according to another embodiment;

FIG. 6 is a partial, perspective view of a power distribution bar according to another embodiment;

FIG. 7 is a simplified, perspective view showing a power rail and a power distribution bar being connected by way of a connector according to another embodiment;

FIG. 8 is a schematic, top plan view of a power rail, a power distribution bar, and a connector in an assembled state according to another embodiment;

FIG. 9 is an enlarged view showing the connection between a conductor of a power rail and a corresponding contact of a connector according to another embodiment;

FIG. 10 is a schematic top plan view of a power distribution system according to another embodiment; and

FIG. 11 is a simplified, perspective view of a power distribution bar having a power usage monitoring unit according to another embodiment.

### DETAILED DESCRIPTION

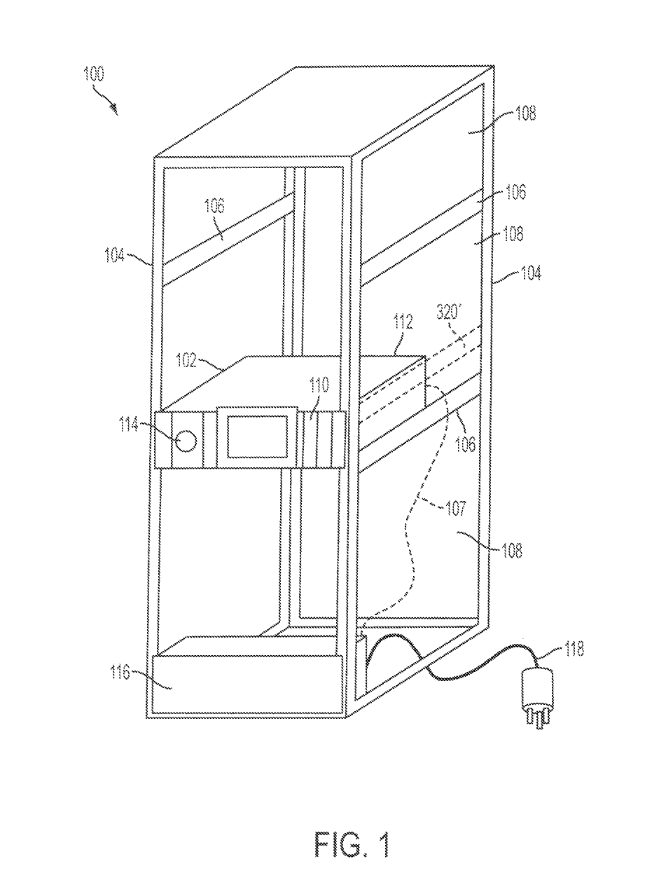

FIG. 1 is a simplified, perspective view of a rack 100 according to an embodiment for housing at least one electrical device 102, such as a computer, server, tape/disk back-up device, household electronic equipment etc. Particularly, an electrical device that is rack-mountable or configurable to be rack-mountable can be used in rack 100.

Rack 100 comprises a number of vertical bars 104, at least one of which is a power distribution bar, and a number of horizontal rails 106, at least one of which is a power rail electrically connected to the power distribution bar for transferring power from the power distribution bar to an electrical device connected to the power rail. The horizontal rails 106 extend transversely to vertical bars 104. Horizontal rails 106 attach to vertical bars 104 at a plurality of positions along vertical bars 104 using fasteners, e.g., screws, snap connectors, rivets, and other (removable and/or non-removable) connection/fastening devices, etc. In at least some embodiments, vertical bars 104 attach to horizontal rails 106.

Horizontal rails 106 attached to vertical bars 104 define a number of cells 108 within rack 100. Each cell 108 is dimensioned to house at least one electrical device 102 by adjusting positions, e.g., vertical spacing, of the respective horizontal rails 106 on vertical bars 104. Electrical device 102 is positioned, e.g., slid, into the respective cell 108, riding on horizontal rails 106 of that cell 108. Fasteners, e.g., screws, can be used to secure a front face 110 of electrical device 102 to at least one vertical bar 104 of rack 100.

Front face 110 of electrical device 102 defines a user interface 114 for allowing a user to manually control or visually monitor a status of electrical device 102. In at least some embodiments, front face 110 lacks a user interface 114. Electrical device 102 further comprises a rear face 112 opposite front face 110. In the preexisting configurations, a power cord 107 is used to connect power terminals of each electrical device 102 on rear face 112 thereof to a power source, such as a PDU 116. Such power cord is not required when a power rail according to an embodiment is provided in cell 108 accommodating electrical device 102. The power rail(s) in rack 100 receive(s) power from either an external power source via power cord 118, or from PDU 116 housed or incorporated in rack 100. In the latter case, power cord 118 provides power to PDU 116 as shown in FIG. 1. In at least some embodiments, power cord 118 is the only power cord that emerges from rack 100. In at least some embodiments, power cord 118 supplies power to one or more electrical devices 102 installed in rack 100 via PDU 116.

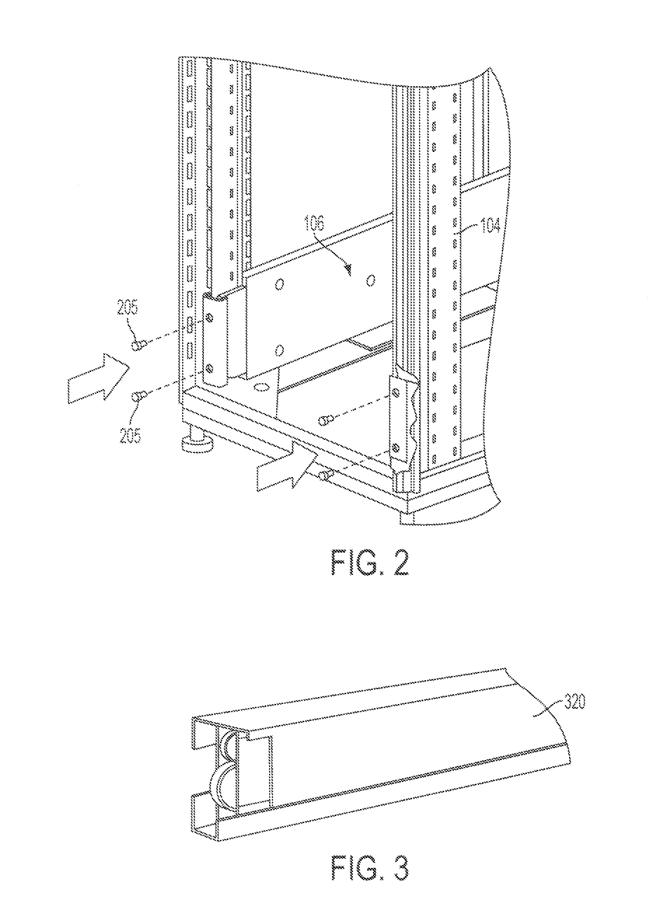

FIG. 2 is a partial, perspective view showing the attachment of horizontal rails 106, including any power rail, to respective vertical bars 104, including any power distribution bar, in rack 100. In particular, horizontal rails 106, including any power rail, attach to vertical bars 104, including any power distribution bar, at a plurality of positions along vertical bars 104 using fasteners, e.g., screws, snap connectors, rivets, and other (removable and/or non-removable) connection/fastening devices, etc. In the embodiment of FIG. 2, screws 205 are used to fasten horizontal rails 106 to respective vertical bars 104.

FIG. 3 is a partially cutaway, perspective view of a power rail 320 according to an embodiment. Power rail 320, in at least one embodiment, replaces one of horizontal rails 106 in each cell 108 of rack 100, and supports and cordlessly supplies power to electrical device 102. In an alternative embodiment, power rail 320 is positioned as part of cell 108 in addition to horizontal rails 106 of the particular cell, and supplies power to electrical device 102 without providing support to the electrical device. Power rail 320 can be attached to vertical bars 104 of rack 100 in a manner similar to horizontal rails 106 as illustrated in FIG. 2.

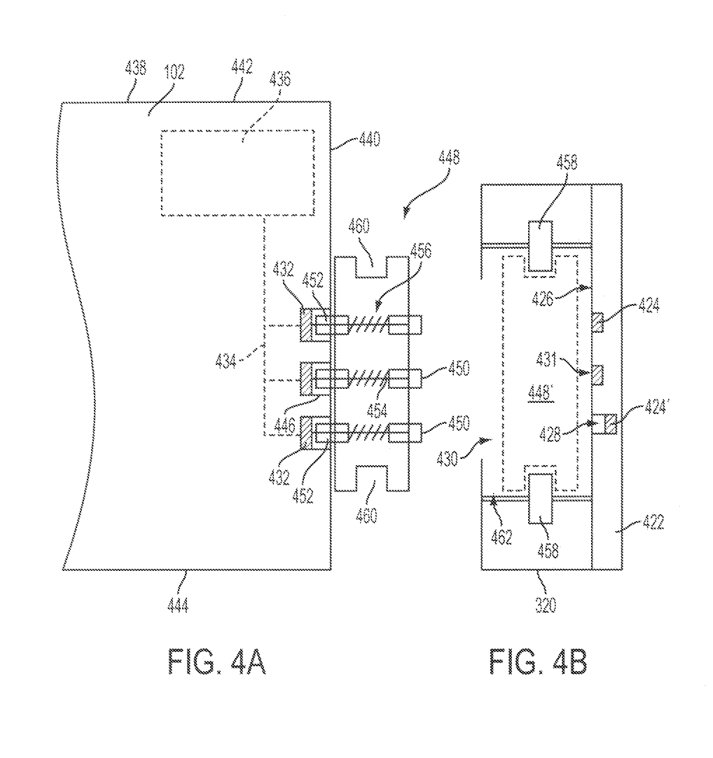

A simplified, cross sectional view of power rail 320 is shown in FIG. 4. Power rail 320, as depicted in FIG. 4, comprises a casing 422 which has embedded therein at least one conductor 424. Casing 422 is made of insulating material or at least comprises insulating material in the vicinity of conductor 424. At least one side of casing 422 is open at opening 430 to allow access to conductor 424. In at least some embodiments, conductor 424 is flush with a surface 426 of casing 422 that faces opening 430, e.g., an inner surface of casing 422. (However, conductors 424 are not necessarily disposed opposite opening 430, and can be positioned anywhere on casing 422, as long as conductors 424 are accessible for sliding contact with power terminals of electrical device 102 as will be described herein below.) One or some or all conductor(s) 424 may be positioned at the bottom of groove 428 formed in surface 426, as shown at 424′ in FIG. 4. The latter configuration prevents a user's fingers from touching conductor 424′. In at least some embodiments, conductors 424 and/or 424′ may be disposed at the same and/or different positions in respective grooves 428. In the description below, conductor 424 and conductor 424′ will be commonly referred to as conductor 424.

The number of conductors 424 in power rail 320 can vary, depending on the power need of electrical device 102. Generally, power rail 320 comprises two conductors 424, one for a hot line and the other for a ground line. For example, for failover protection, three or more conductors 424 connected to at least two hot lines and a ground line, respectively, can be provided to connect two or more independent power sources to electrical device 102, to ensure continuous power supply to electrical device 102 in the event of failure of power supplied from one of the conductors. In another embodiment, only a few, not all, of multiple conductors 424 provided in power rail 320 are used for feeding electrical device 102, whereas the remaining conductors 424 are disabled, either by an external power source, e.g., PDU 116, or by a connector.

Each conductor 424 has a surface 431 at least partially uninsulated and exposed for contact with and providing power to a respective power terminal 432 of electrical device 102. Power terminals 432 are connected by electrical conducting connecting lines 434 to a power supply unit (PSU) 436 of electrical device 102. Connecting lines 434 extend inside a case 438 of electrical device 102. Power terminals 432 are provided on a side wall 440 of case 438. In at least some embodiments, power terminals 432 may be provided elsewhere, e.g., on top wall 442 or bottom wall 444, of case 438. Power terminals 432 can be flush with or project outwardly from the outer surface of side wall 440. Power terminals 432 are provided inside case 438 and exposed through openings 446 for safety reasons. An adapter 448 is used to electrically connect power terminals 432 of electrical device 102 with respective conductors 424 of power rail 320.

Adapter 448 comprises two sets of contacts, namely 450 and 452, for electrical connection to conductors 424 and power terminals 432, respectively. Contacts 450 and 452 are respectively electrically connected to each other within adapter 448 as schematically shown at 454. A spring 456 biasing contacts 450 and 452 in each pair away from each other, toward the respective conductor 424 and power terminal 432, in use, to ensure reliable contact and power supply from power rail 320 to electrical device 102. An individual spring can be provided for each contact 450 or 452, i.e., two springs for each pair of contacts 450, 452. In alternative embodiments, springs 46 are omitted and/or incorporated in contacts 450, 452. In the latter case, each contact 450 or 452 is configured as a leaf spring which, in use, presses against the respective conductor 424 or power terminal 432. In a further embodiment, only one set of contacts, e.g., 450, are moving contacts or spring-loaded, whereas the other set of contacts, i.e., 452, are stationary contacts.

Adapter 448 can be attached to case 438, in a particular embodiment to side wall 440, in any appropriate manner including, but not limited to, screw connection, snap connection, adhesive bonding, welding, molding etc. In at least some embodiments, adapter 448 may be an integral part of case 438.

Adapter 448 and power rail 320 have matching coupling elements that allow adapter 448, and hence, electrical device 102 to be moveable along power rail 320 while maintaining a predetermined distance between electrical device 102 and power rail 320, thereby effecting reliable surface-to-surface contact between power terminals 432 and conductors 424. The coupling elements comprise wheels 458 rotatably supported in casing 422 of power rail 320, and matching grooves 460 formed in adapter 448. In use, adapter 448 is attached to electrical device 102 and then inserted in power rail 320 through a front, open end of power rail 320. Adapter 448 is thus received in an interior 462 of power rail 320 as shown at 448′ in FIG. 4. In such assembled state, wheels 458 ride in respective grooves 460 to guide adapter 448 moving along power rail 320.

During movement of adapter 448 along power rail 320, contacts 450 are in sliding contact with respective conductors 424, thereby powering electrical device 102 while electrical device 102 moves relative to power rail 320. Power is thus transferred cordlessly from power rail 320 to electrical device 102.

In an embodiment, conductors 424 are elongated in the longitudinal direction of power rail 320, and extend a substantial length of power rail 320. Thus, electrical device 102 is powered by conductor 424 as electrical device 102 moves along the substantial length of power rail 320. In at least some other embodiments, conductor 424 extends only a partial length of power rail 320 near the final destination of electrical device 102. Thus, electrical device 102 is not powered by power rail 320 at the beginning of its movement along the power rail, and is powered by conductor 424 as it approaches the final destination.

In an embodiment, wheels 458 are omitted and replaced by ridges slidable in grooves 460. In at least some other embodiments, the positions of the coupling elements are switched, i.e., wheels or ridges 458 are provided on adapter 448, whereas grooves 460 are formed inside casing 422 of power rail 320.

In at least one further embodiment, the coupling elements are omitted when the distance between electrical device 102 and power rail 320 is maintained by another engagement between electrical device 102 and rack 100. For example, electrical device 102 in this embodiment is slidably supported by two horizontal rails 106 of rack 100, and power rail 320 is provided adjacent to and in parallel to at least one of the horizontal rails 106 (as shown at 320′ in FIG. 1) only for the purpose of powering electrical device 102.

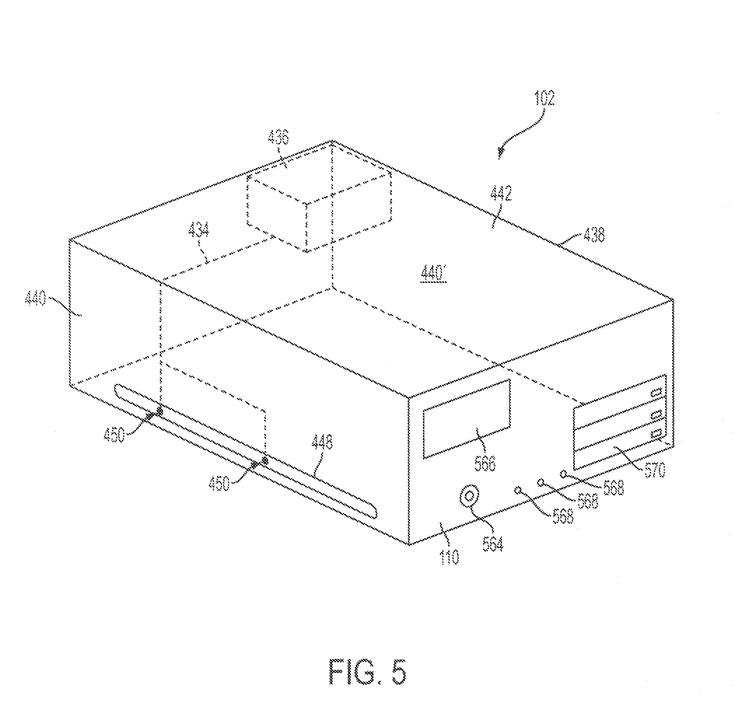

FIG. 5 is a simplified, perspective view of electrical device 102 according to at least one embodiment. Electrical device 102 comprises front face 110 on which a user interface is provided for allowing a user to manually control or monitor operation of electrical device 102. In a particular embodiment, the user interface comprises at least one of a power button 564, a screen or see-through window 566, a number of control buttons 568, and one or more disk drive or tape cartridge slot 570. PSU 436 is positioned inside case 438 of electrical device 102, and connected to adapter 448 via connecting line(s) 434. Adapter 448 is elongated in the sliding direction of electrical device 102 and provided on side wall 440 of case 438. Contact(s) 450 and the matching contact(s) 452 are provided at one or more positions on adapter 448. One of the coupling elements, e.g., grooves 460, extends longitudinally of adapter 448 for moveable engagement with the matching coupling element, e.g., wheels 458, of power rail 320. Electrical device 102 is thus both supported for sliding movement and powered by power rail 320. A similar adapter 448 in an alternative embodiment is provided on the opposite side wall 440′ of case 438, and hence, electrical device 102 rides on and receives power from two power rails 320. In another alternative embodiment, adapter 448 is provided on only one side wall 440, and the electrical device 102 is slidably supported on the opposite side by a horizontal rail 106 which is not a power rail 320.

In at least some embodiments, a kit comprising a power rail, such as power rail 320, and an adapter, such as adapter 448, is provided. The kit is usable to upgrade an electrical device, such as 102, which is initially configured to receive power supply via a power cord, to be cordlessly powerable. In use, adapter 448 is attached to side wall 440 of electrical device 102 so that contacts 452 are in electrical contact with respective power terminals 432. Electrical device 102 is then slid into a cell 108 of rack 100, where power rail 320 has been installed, to cordlessly receive power from power rail 320. No power cord, such as 107 in FIG. 1, is used to supply power to electrical device 102. Electrical device 102 is disconnected from the power supply simply by removing electrical device 102 from cell 108, and hence, disengaging/disconnecting adapter 448 from power rail 320.

In at least one other embodiment, a kit further comprises a side panel comprising power terminals, such as 432, to replace a side wall 440 of electrical device 102. Such replacement side panel in an embodiment comes with connecting lines 434 for connection with PSU 436 by a plug/receptacle connection. Since connecting lines 434 are within case 438, no power cord sticks out. The replacement side panel can be detachably attachable to or permanently integrated with adapter 448.

In yet further embodiments, a kit also comprises a power distribution bar and/or a connector.

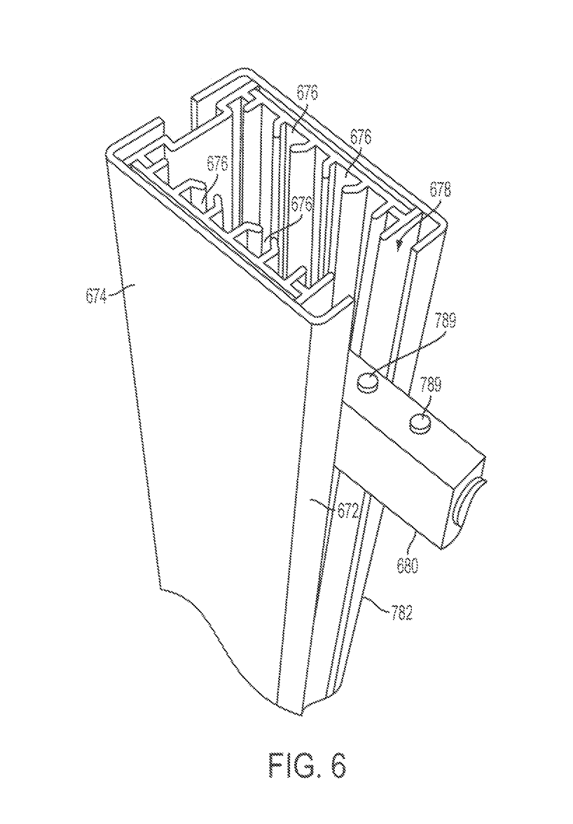

FIG. 6 is a partial, perspective view of a power distribution bar 672 according to a further embodiment. Power distribution bar 672 replaces at least one of vertical bars 104 of rack 100. In another embodiment, power distribution bar 672 is added to rack 100 as an additional component. Several power distribution bars 672 are used in a single rack in accordance with a further embodiment for satisfying the varying power consumption demand of the equipment installed in the rack.

Similar to power rail 320, power distribution bar 672 comprises a casing 674 having embedded therein a number of elongated conductors 676 extending longitudinally of power distribution bar 672. An opening 678 is provided on a wall of casing 674 to allow access to conductors 676. The number of conductors 676 is dictated by the specific application and is customizable and/or controllably disabled/enabled as discussed above with respect to conductors 424 of power rail 320. In an embodiment, opening 678 extends the whole or substantial length of power distribution bar 672. In another embodiment, there are several openings 678 distributed along power distribution bar 672 at positions where electrical connection to power rails, such as 320, is desirable. A power rail 320 is electrically connectable to power distribution bar 672 at any place along the length of power distribution bar 672, or at any of the desirable positions mentioned above. Power distribution bar 672 is electrically connected to either PDU 116 or power cord 118 for receiving power from an external power source, and for subsequently distributing the received power to one or more power rails 320 attached at various positions to said power distribution bar 672.

The electric connection between power distribution bar 672 and power rail 320 is effected by a connector 680 partially shown in FIG. 6. A simplified, perspective view showing connector 680 is provided in FIG. 7 which also depicts a power rail 320 and a power distribution bar 672 being connected by way of connector 680 according to a further embodiment. Connector 680 comprises a first connecting member 782 and a second connecting member 784 for electrical connection to power distribution bar 672 and power rail 320, respectively.

First connecting member 782 comprises a plurality of first terminals 789 for electrical connection with respective conductors 676 of power distribution bar 672. As best seen in FIG. 6, second connecting member 784 has four first terminals 789 (only two are visible in FIG. 6), two on each side, to correspond to conductors 676 of power distribution bar 672 which are also distributed two on each side within the interior of power distribution bar 672. In at least some embodiments, first terminals 789 are positioned all on one side of first connecting member 782 as shown in the embodiment of FIG. 7.

Returning to FIG. 6, first connecting member 782 is insertable, e.g., by a user, into the interior of power distribution bar 672 through opening 678, with first terminals 789 projecting generally axially of power distribution bar 672. Once first connecting member 782 has reached a position that aligns first terminals 789 with conductors 676, first connecting member 782 is rotatable, e.g., by a user, about 90 degrees, to force first terminals 789 into contact with respective conductors 676, and at the same time, fix first connecting member 782, and hence connector 680, in place relative to power distribution bar 672. Thus, a twist-lock connection is effected between connector 680 and power distribution bar 672. In an embodiment, first terminals 789 are spring-loaded for reliable contact with respective conductors 676 in the twist-lock connection. Power is thus cordlessly transferred from power distribution bar 672 to connector 680.

Second connecting member 784 comprises a plurality of second terminals 786 connected to respective first terminals 789 as schematically illustrated at 795 in FIG. 7. Second terminals 786 are further electrically connectable to conductors 424 of power rail 320, either directly or through matching terminals formed at a rear end 787 of power rail 320.

FIG. 9 depicts a configuration of a terminal 988 formed at rear end 787 of power rail 320. The corresponding second terminal 786 has a shape 990 generally complementary to that of terminal 988. In particular, second terminal 786 is press-fit inside terminal 988 to form a plug/socket connection. Thus, a reliable connection between power rail 320 and second connecting member 784 can be effected simply by sliding power rail 320 towards connector 680 until second terminals 786 are snapped in and make contact with respective terminals 988. In this embodiment, again, power is cordlessly transferred, this time from connector 680 to power rail 320.

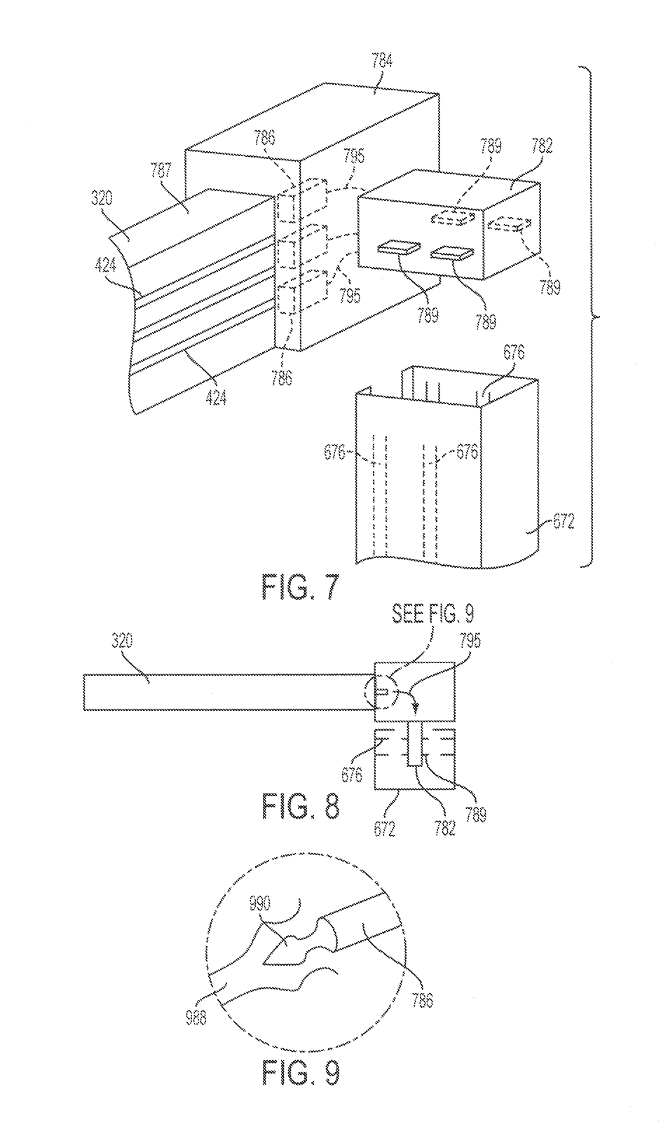

FIG. 8 depicts a complete, assembled state between power distribution bar 672, connector 680 and power rail 320.

In at least some embodiments, connector 680 is integrated with one of power rail 320 and power distribution bar 672. However, the above disclosed embodiments with separate connector 680, power rail 320 and power distribution bar 672, which are releasably connectable, allows for desirable flexibility in the rack's configuration where connector 680, and hence power rail 320, can be attached at a position along a substantially entire length of power distribution bar 672.

In a further embodiment, connector 680 is configurable to enable or disable one or more of connections 795, thereby selectively transferring power only from desired conductors 676 of power distribution bar 672 to corresponding desired conductors 424 of power rail 320, depending on the power need of the electrical device 102 being installed.

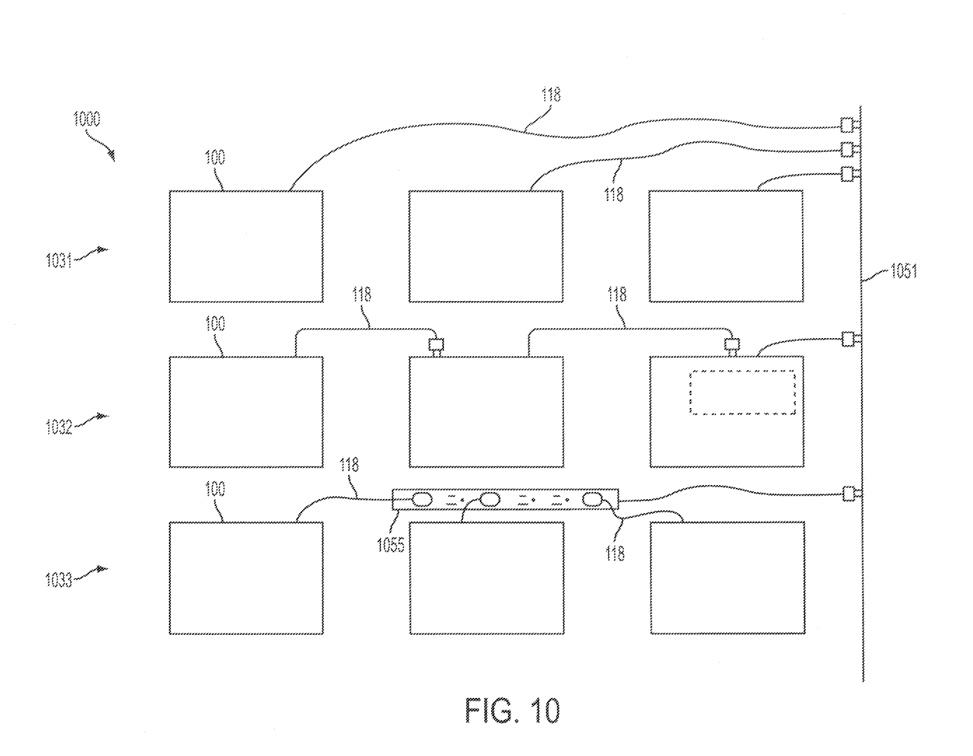

FIG. 10 is a schematic top plan view of a power distribution system 1000 according to a further embodiment. System 1000 comprises a plurality of racks 100 arranged as an array having a plurality of rows 1031-1033. All electrical devices 102 held in each rack 100 are cordlessly powered by one or more power rails and/or power distribution bars and/or connectors and adapters. Each rack is, in turn, powered via, e.g., a power cord 118. Racks 100 in a row, e.g., 1031, can be individually connected to a power source schematically designated at 1051. Racks 100 in a row, e.g., 1032, can be connected in cascade to power source 1051. A power strip, such as 1055, can be used to connect racks 100 in a row to power source 1051. System or array 1000 of racks 100 therefore greatly reduces the number of power cords that would be otherwise necessary to feed all equipment held by racks 100. In addition, installation or removal of equipment is also greatly simplified by merely inserting or withdrawing the equipment to/from a rack without having to plug or unplug a power cord on the back of the equipment to/from a power socket.

In at least some embodiments, power source 1051 is a breaker panel connected to one or more independent 1- or multiple-phase power sources.

System 1000, in a further embodiment, allows to distribute load on demand, and to create an adaptive power solution. The system is modular and the rows are expandable to create a modular power grid.

In at least another embodiment, each rack 100 or row 1031-1033 comprises a unit for monitoring power usage. A power profile for entire row of racks 100 is obtainable on line, e.g., with a cabinet monitoring system (CMS).

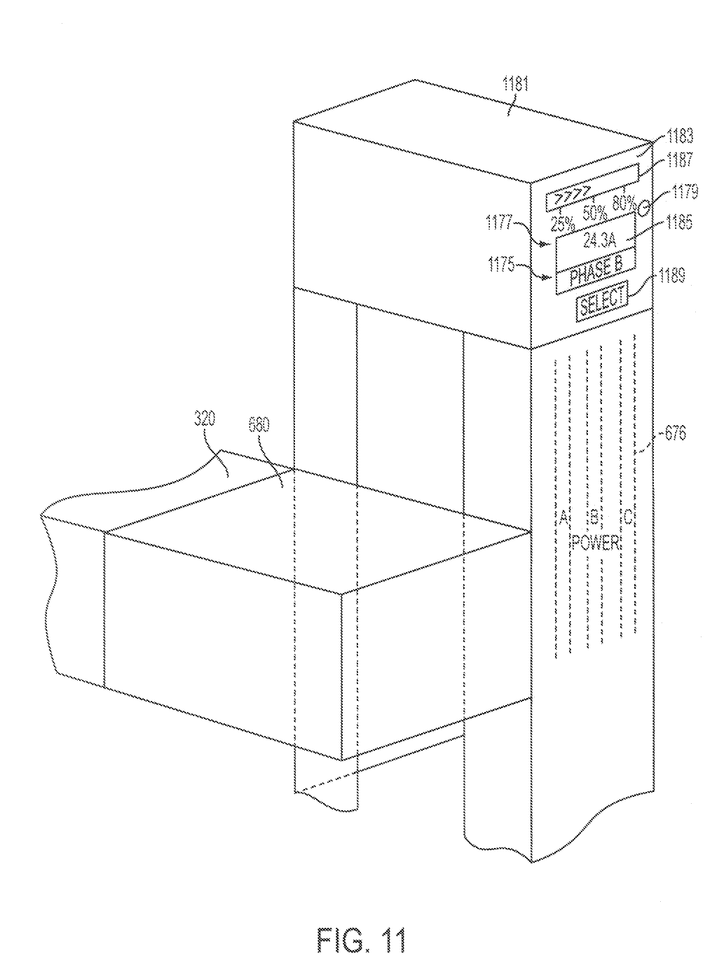

Power usage monitoring can also be performed at the rack/cabinet level. FIG. 11 is a simplified, perspective view of a power distribution bar 672 comprising a power usage monitoring unit 1181 according to a further embodiment. Power usage monitoring unit 1181 in the embodiment of FIG. 11 is placed at an upper end, in use, of power distribution bar 672. In at least some embodiments, power usage monitoring unit 1181 can be positioned anywhere along power distribution bar 672, e.g., in the middle, at the eye level, or at the lower end.

Power usage monitoring unit 1181 comprises a detector electrically coupled to one or more of conductors 676 of power distribution bar 672 for detecting at least one parameter of the power transmission through the particular conductor 676. In the embodiment of FIG. 11, the detector is a power and/or voltage and/or current meter that measures, in use, the power transmission through the entire power distribution bar 672.

Power usage monitoring unit 1181 further comprises at least an indicator 1183, visual or audible, for conveying information related to the detected parameter(s) to a user or operator. In the embodiment of FIG. 11, indicator 1183 comprises at least one of a display 1185, a visual load indicator 1187, one or more control button 1189, and a sound generating device 1179, such as a speaker or alarm.

Visual load indicator 1187 indicates a ratio, in percentage, of the current load and maximum load of power distribution bar 672. The ratio is presented as a lighted bar or blocks that change(s) color, e.g., from green to red, when the ratio reaches or exceeds a predetermined value, e.g., 80%, to warn that no further equipment should be connected to that power distribution bar 672. At the same time or at a higher current load/maximum load ratio, an audible alarm is generated through speaker 1179 to alert the operator of the critical situation.

Display 1185 indicates the measured value of the detected parameter. In the embodiment of FIG. 11, display 1185 is divided into two displaying areas 1175 and 1177, one (1177) for displaying the measured value and the other (1175) for indicating the conductor(s) 676 where the value is measured. for example, if conductors 676 of power distribution bar 672 are connected to phases A, B and C of a three-phase power source, displaying area 1175 indicates the phase (or conductor 676) being monitored and displaying area 1177 displays the current on that phase.

Control button(s) 1189 is/are provided for allowing the operator to switch display 1185 among a number of parameters monitored by power usage monitoring unit 1181, such as total KVA, input voltage, current etc. Control button(s) 1189 can also be used to input certain settings, such as the current load/maximum load ratio at which the alarm 1179 is triggered.

What is claimed is:

1. A power rail, comprising:
a portion for guiding an electrical device to slide along said power rail; and
at least a conductor having a surface which is at least partially un-insulated and exposed for contact with a power terminal of the electrical device, for cordlessly supplying power to the electrical device when the electrical device is guided by said portion to slide along said power rail.

2. The power rail of claim 1, wherein
said conductor and the at least partially un-insulated surface thereof are elongated in a longitudinal direction of said rail for sliding contact with the power terminal of the electrical device.

3. The power rail of claim 2, comprising
multiple parallel said conductors each configured for connection to a corresponding one among multiple said power terminals of the electrical device, thereby providing failover protection for the electrical device.

4. The power rail of claim 1, further comprising:
a connector electrically connecting said conductor to a corresponding conductor of a power distribution bar of a rack for holding the electrical device.

5. A rack, comprising:
a plurality of bars; and
a plurality of rails transverse to the bars;
said bars and rails being attached to one another to define a frame having a plurality of slots each for receiving at least one electrical device;
wherein
at least one of said rails is a power rail comprising at least a first conductor having a surface which is at least partially un-insulated and exposed for contact with a power terminal of the electrical device to be received in the respective slot, for cordlessly supplying power to the electrical device;
at least one of said bars is a power distribution bar comprising a second conductor extending longitudinally of said bar and electrically contacting said first conductor.

6. The rack of claim 5, wherein
each of said power rail and power distribution bar comprises multiple first and second conductors, respectively; and
said multiple first and second conductors are respectively connected with one another to provide failover protection for the electrical device.

7. The rack of claim 5, wherein
at least one of said power rail and power distribution bar has a hollow interior; and
the respective conductor of said at least one of said power rail and power distribution bar is embedded in an inner wall of said rail or bar and exposed to said interior.

8. The rack of claim 7, wherein
said power distribution bar has on a side wall thereof at least one opening leading into the hollow interior of the power distribution bar; and
said power rail has a connector extending through said opening into the hollow interior of the power distribution bar to contact the second conductor for electrically connecting the first and second conductors.

9. The rack of claim 5, comprising
multiple said power rails adjustably mountable at a number of positions along said power distribution bar so that each of said slots comprises at least one said power rails.

10. The rack of claim 9, having a single power cord for supplying power from a power source to all said power rails and power distribution bars, as well as all electrical devices received in the slots of said rack.

11. An electrical device, comprising:
a case; and
at least a power terminal exposed on an outer surface of said case for surface-to-surface contact with a power rail;
wherein
said case has a front wall defining a user interface; and
said power terminal is exposed on the outer surface of a side wall or bottom wall or top wall of said case.

12. A rack-mounted computer center, comprising:
a rack as defined in claim 5; and
at least one computer mounted in at least one said slot of said rack;
said computer comprising:
a case; and
at least a power terminal exposed on an outer surface of said case and in surface-to-surface contact with the first conductor of the power rail in said slot for cordlessly receiving power from said power rail.

13. The rack-mounted computer center of claim 12, wherein
said case has a front wall defining a user interface for allowing a user to manually control or visually monitor a status of said computer; and
said power terminal is exposed on the outer surface of a side wall or bottom wall of said case.

14. The rack-mounted computer center of claim 12, wherein
said computer is removably received in said slot and slidably supported by the rails, including the power rail, of said slot; and
said power terminal of said computer is in constant and sliding contact with the first conductor of said power rail as the computer slides along the power rail.

15. The rack-mounted computer center of claim 12, wherein
said computer is exclusively cordlessly powered by said power rail.

16. A power distribution bar, comprising:
at least one conductor running longitudinally of said bar and at least partially un-insulated and exposed at locations where one or more power rails are attachable for electrical connection to the at least one conductor.

17. The power distribution bar of claim 16, further comprising a power usage monitoring unit comprising:
a detector coupled to said at least one conductor for detecting at least one parameter of the power transmission through said bar; and
at least one visual or audible indicator of the detected parameter.

18. The power distribution bar of claim 16, comprising multiple parallel said conductors.

19. The power distribution bar of claim 16, having a hollow interior, wherein
the conductor is embedded in an inner wall of said bar and exposed to said interior.

20. The power distribution bar of claim 19, wherein
said power distribution bar has on a side wall thereof at least one opening leading into the hollow interior of the power distribution bar; and
said at least one opening being at least one of
elongated longitudinally of said bar, and
present at the locations where said conductor is electrically connectable to the one or more power rails attached thereto.

21. A power distribution system, comprising multiple racks as defined in claim 5;
the power distribution bars of said racks being electrically connected to each other.

22. The power distribution system of claim 21, wherein said racks being arranged in one or more rows,
the power distribution bars of the racks in each said row being electrically connected to each other and to a common power source.

23. The power distribution system of claim 22, further comprising
for each said row, a power usage monitor.

24. A power distribution method, comprising:
connecting a rack as defined in claim 5 to a power source; and
cordlessly powering an electrical device by placing the electrical device in a slot of said rack where the power rail is provided.

25. The method of claim 24, further comprising:
sliding said electrical device along said power rail without interrupting cordless power supply to said electrical device.

26. The method of claim 24, further comprising:
discontinuing power supply to said electrical device solely by removing the electrical device from said slot without unplugging any power cord.

27. A kit, comprising a power rail and an adapter;
said power rail comprising at least a conductor having a surface which is at least partially un-insulated and exposed for contact with a power terminal of the electrical device, for cordlessly supplying power to the electrical device; and
an adapter moveably retainable within said power rail and attachable to the electrical device for electrically connecting the power terminal of the electrical device with the conductor of said power rail along a length of said power rail.

28. The kit of claim 27, further comprising
a power distribution bar comprising at least one matching conductor running longitudinally of said bar and at least partially un-insulated and exposed at locations where said power rail is attachable for electrical connection between said conductors.

29. The kit of claim 28, further comprising
a connector releasably attachable to both said power rail and said power distribution bar at a corner defined by said power rail and power distribution bar, for electrically connecting the conductors of said power rail and said power distribution bar at said corner.

30. The kit of claim 27, further comprising
a replacement side panel attached or attachable to said adapter, carrying thereon a power terminal, and adapted to replace a corresponding side wall of the electrical device;
wherein the power terminal carried by the replacement side panel is connectable to a power supply unit of the electrical device for functioning as a power terminal of said electrical device and contacting the conductor of the power rail in use.
